(19) United States
(12) Patent Application Publication
(10) Pub. No.: US 2025/0175143 A1
(43) Pub. Date: May 29, 2025

(54) ACOUSTIC WAVE DEVICE, HIGH FREQUENCY MODULE, AND COMMUNICATION DEVICE

(71) Applicant: Murata Manufacturing Co., Ltd., Kyoto (JP)

(72) Inventors: Shogo YANASE, Kyoto (JP); Mizuki KINOSHITA, Kyoto (JP); Takanori UEJIMA, Kyoto (JP); Ryoya SHIOMI, Kyoto (JP); Yuusuke KISHI, Kyoto (JP); Masaki TADA, Kyoto (JP); Nanami YUMURA, Kyoto (JP)

(21) Appl. No.: 18/904,390

(22) Filed: Oct. 2, 2024

(30) Foreign Application Priority Data
Nov. 28, 2023 (JP) 2023-201121

(51) Int. Cl. H03H 9/05; H03H 9/02; H03H 9/10

(52) U.S. Cl. CPC H03H 9/059; H03H 9/02913; H03H 9/1085

(57) ABSTRACT

An acoustic wave device includes a substrate, an outer connection electrode arranged on a first principal surface of the substrate, and an outer shield layer arranged on side surfaces of the substrate. The substrate has the first principal surface and a second principal surface that are mutually opposed, and the side surfaces connecting the first principal surface and the second principal surface together. The outer connection electrode has a tip surface exposed.

### CROSS REFERENCE TO RELATED APPLICATION

This application claims priority from Japanese Patent Application No. 2023-201121 filed on Nov. 28, 2023. The content of this application is incorporated herein by reference in its entirety.

### BACKGROUND OF THE DISCLOSURE

### 1. Field of the Disclosure

The present disclosure relates to acoustic wave devices, high frequency modules, and communication devices and, in particular, relates to an acoustic wave device including an outer shield layer, a high frequency module including the acoustic wave device, and a communication device including the high frequency module.

### 2. Description of the Related Art

International Publication No. 2022/102288 discloses a high frequency module including a transmission filter and a reception filter, which are acoustic wave filters (acoustic wave devices). The high frequency module of International Publication No. 2022/102288 includes a metal shield wall between the transmission filter and the reception filter, and a metal shield wall between the transmission filter and another component of the high frequency module. The metal shield walls improve the isolation between the transmission filter and the reception filter and the isolation between the transmission filter and another component.

### BRIEF SUMMARY OF THE DISCLOSURE

However, in the high frequency module of International Publication No. 2022/102288, since the metal shield walls are required, it is difficult to reduce the size of the high frequency module.

A possible benefit of the present disclosure is to provide an acoustic wave device capable of reducing the size of a module where a plurality of components including an acoustic wave device are arranged, and a high frequency module and communication device including the acoustic wave device.

An acoustic wave device according to an aspect of the present disclosure includes a substrate, an outer connection electrode, and an outer shield layer. The substrate has a first principal surface and a second principal surface that are mutually opposed, and side surfaces connecting the first principal surface and the second principal surface together. The outer connection electrode is arranged on the first principal surface of the substrate. The outer shield layer is arranged on the side surfaces of the substrate. The outer connection electrode has a tip surface exposed.

A high frequency module according to another aspect of the present disclosure includes the above-described acoustic wave device, and a mount substrate. The acoustic wave device is arranged on the mount substrate.

A communication device according to still another aspect of the present disclosure includes the above-described high frequency module, and a signal processing circuit to be connected to the high frequency module.

According to the acoustic wave device, the high frequency module, and the communication device of an aspect of the present disclosure, it is possible to reduce the size of a module where a plurality of components including an acoustic wave device are arranged.

### BRIEF DESCRIPTION OF THE SEVERAL VIEWS OF THE DRAWINGS

FIG. 1 is a plan view of an acoustic wave device according to a first embodiment;

FIG. 2 is a sectional view of the acoustic wave device according to the first embodiment, and corresponds to an X1-X1 plane of FIG. 1;

FIG. 3 is a sectional view of the acoustic wave device according to the first embodiment, and corresponds to an X2-X2 plane of FIG. 1;

FIG. 4 is a sectional view of an acoustic wave device according to a second embodiment;

FIG. 5 is a sectional view of the acoustic wave device according to the second embodiment, and corresponds to a section different from that of FIG. 4;

FIG. 6 is a circuit structure diagram of a communication device according to the second embodiment;

FIG. 7 is a partial sectional view of a high frequency module according to the second embodiment;

FIG. 8 is a partial sectional view of a high frequency module according to a third embodiment;

FIG. 9 is a partial sectional view of a high frequency module according to a modification of the third embodiment;

FIG. 10 is a partial sectional view of a high frequency module according to a fourth embodiment;

FIG. 11 is a partial sectional view of a high frequency module according to a first modification of the fourth embodiment;

FIG. 12 is a partial sectional view of a high frequency module according to a second modification of the fourth embodiment;

FIG. 13 is a partial sectional view of a high frequency module according to a fifth embodiment;

FIG. 14 is a partial sectional view of a high frequency module according to a first modification of the fifth embodiment;

FIG. 15 is a partial sectional view of a high frequency module according to a second modification of the fifth embodiment;

FIG. 16 is a partial plan view of a high frequency module according to a sixth embodiment;

FIG. 17 is a partial sectional view of the high frequency module according to the sixth embodiment, and corresponds to an X3-X3 section of FIG. 16;

FIG. 18 is a partial sectional view of a high frequency module according to a seventh embodiment;

FIG. 19 is a plan view of a high frequency module according to an eighth embodiment;

FIG. 20 is a plan view of a high frequency module according to a ninth embodiment; and

FIG. 21 is a plan view of a high frequency module according to a first modification of the ninth embodiment.

### DETAILED DESCRIPTION OF THE DISCLOSURE

A high frequency module and a communication device according to embodiments are described below by using the drawings. Drawings to be referred to in the following embodiments are schematic drawings, and ratios in size and thickness of components in the drawings do not necessarily reflect actual dimensional ratios.

### First Embodiment

### 1 Acoustic Wave Device

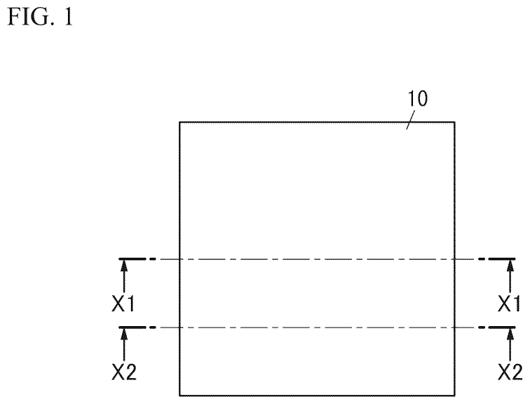

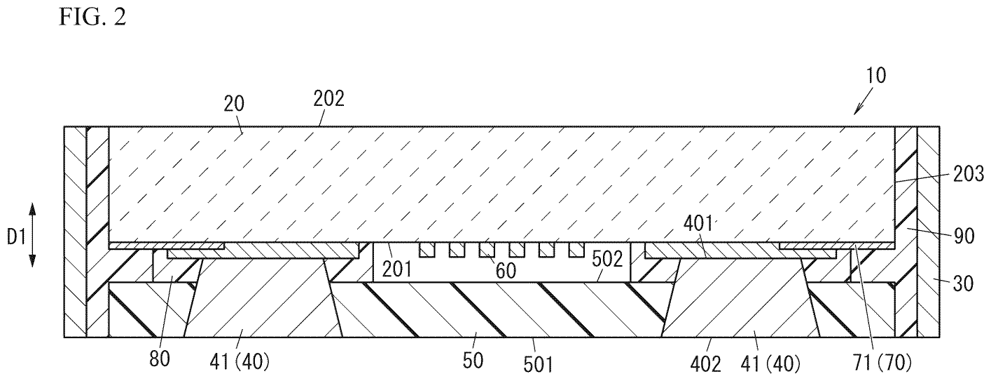

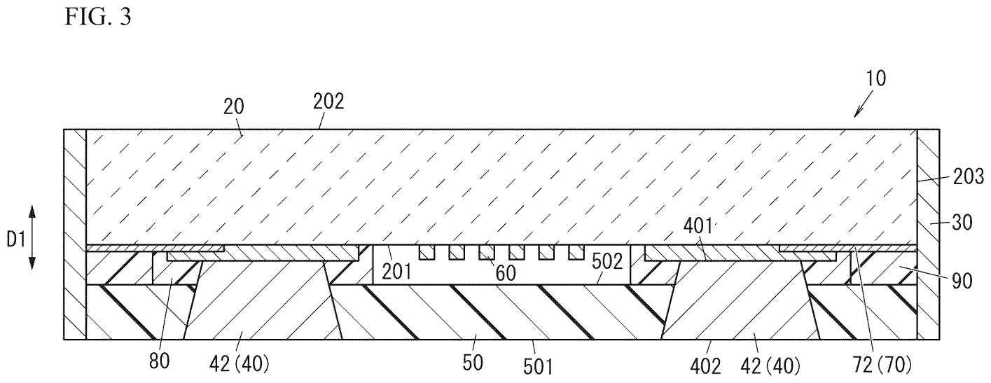

An acoustic wave device 10 according to a first embodiment includes, as depicted in FIG. 1 to FIG. 3, a substrate 20, an outer shield layer 30, and a plurality of outer connection electrodes 40. Also, the acoustic wave device 10 includes, as depicted in FIG. 2 and FIG. 3, a cover layer 50, a functional electrode 60, a wiring layer 70, a support layer 80, and a resin layer 90.

### 1.1 Substrate

The substrate 20 is, for example, a substrate with piezoelectricity. More specifically, the substrate 20 is, for example, a piezoelectric substrate. The material of the piezoelectric substrate is, for example, lithium tantalate, lithium niobate, or crystal.

The substrate 20 has, as depicted in FIG. 2 and FIG. 3, a first principal surface 201 and a second principal surface 202, and side surfaces 203. The first principal surface 201 and the second principal surface 202 are mutually opposed in a thickness direction of the substrate 20 (hereinafter referred to as a “first direction D1”). The side surfaces 203 connect the first principal surface 201 and the second principal surface 202 together. In plan view from the first direction D1, the substrate 20 has a square shape. However, the shape is not limited to this and may be, for example, a rectangular shape.

### 1.2 Cover Layer

The cover layer 50 is, for example, in a flat shape. While the cover layer 50 has a square shape in plan view from the first direction D1, the shape is not limited to a square shape and may be, for example, a rectangular shape. The cover layer 50 has a size substantially equal to that of the substrate 20 in plan view from the first direction D1. The cover layer 50 is arranged on the support layer 80. The cover layer 50 has a fourth principal surface 501 and a third principal surface 502 mutually opposed in the first direction D1. The third principal surface 502 of the cover layer 50 and the first principal surface 201 of the substrate 20 are mutually opposed in the first direction D1. Also, the third principal surface 502 of the cover layer 50 is exposed.

The cover layer 50 has electrical insulation properties. The cover layer 50 contains, for example, resin and a filler. The resin is, for example, epoxy resin, polyimide resin, or phenol resin, but is not limited to these materials. The material of the filler is, for example, an inorganic material. The material of the filler is an inorganic material such as, for example, silica oxide or ceramic, but is not limited to these.

### 1.3 Outer Shield Layer

The outer shield layer 30 is arranged on the side surfaces 203 of the substrate 20. More specifically, the outer shield layer 30 is, as depicted in FIG. 2 and FIG. 3, a prism-shaped member covering all of the side surfaces of the substrate 20. Note that the outer shield layer 30 may further cover the second principal surface 202 of the substrate 20.

The outer shield layer 30 has a multilayer structure with a plurality of metal layers laminated together. However, the structure is not limited to the multilayer structure, and may be formed of one metal layer. The one metal layer contains one or more types of metal.

### 1.4 Outer Connection Electrode

The plurality of outer connection electrodes 40 electrically connect an electrode of a mount substrate of a module where the acoustic wave device 10 is arranged and the wiring layer 70. The material of the outer connection electrodes 40 is an appropriate metal material such as, for example, copper, nickel, or an alloy having any of these metals as a main component.

The plurality of outer connection electrodes 40 each penetrate through the cover layer 50 in the first direction D1. The plurality of outer connection electrodes 40 each have a tip surface 401 at one end and a tip surface 402 at the other end in the first direction D1. The tip surface 401 of the outer connection electrode 40 is connected to the functional electrode 60 or the wiring layer 70 on the first principal surface 201 of the substrate 20. That is, the plurality of outer connection electrodes 40 are each arranged on the first principal surface 201 of the substrate 20.

The tip surface 402 of each of the plurality of outer connection electrodes 40 is exposed.

The tip surface 402 of each of the plurality of outer connection electrodes 40 is arranged so as to be flush with the fourth principal surface 501 of the cover layer 50. Therefore, when the acoustic wave device 10 is arranged on the mount substrate of the module, it is possible to shorten a distance between the fourth principal surface 501 of the cover layer 50 of the acoustic wave device 10 and the principal surface of the mount substrate of the module where the acoustic wave device 10 is arranged in the first direction D1. Therefore, the size of the high frequency module including the acoustic wave device 10 can be reduced.

The plurality of outer connection electrodes 40 each include a first connection electrode 41 connected to the functional electrode 60 and a second connection electrode 42 connected to the outer shield layer 30.

### 1.5 Functional Electrode

The functional electrode 60 is arranged on the first principal surface 201 of the substrate 20. The functional electrode 60 includes, for example, an interdigital transducer (IDT) electrode. The material of the IDT electrode is an appropriate metal material such as, for example, aluminum, copper, platinum, gold, silver, titan, nickel, chromium, molybdenum, tungsten, or an alloy having any of these metals as a main component. Also, the IDT electrode may have a structure in which a plurality of metal films made of any of these metals or alloys are laminated.

### 1.6 Wiring Layer

The wiring layer 70 is arranged on the first principal surface 201 of the substrate 20. The wiring layer 70 includes a wiring portion 71 and a wiring portion 72. The wiring portion 71 electrically connects the first connection electrode 41 and the functional electrode 60 together. The wiring portion 72 electrically connects the second connection electrode 42 and the outer shield layer 30 together. The material of the wiring layer 70 is an appropriate metal material such as, for example, aluminum, copper, platinum, gold, silver, titan, nickel, chromium, molybdenum, tungsten, or an alloy having any of these metals as a main component. Also, the wiring layer 70 may have a structure in which a plurality of metal films made of any of these metals or alloys are laminated.

### 1.7 Support Layer

The support layer 80 is formed, as depicted in FIG. 2 and FIG. 3, on the first principal surface 201 of the substrate 20, and is arranged between the substrate 20 and the cover layer 50 in the first direction D1.

The support layer 80 is, for example, in a rectangular shape in plan view from the first direction D1, and surrounds the functional electrode 60.

The support layer 80 has electrical insulation properties. The material of the support layer 80 is, for example, synthetic resin such as epoxy resin or polyimide. Note that the support layer 80 does not include a filler. Note that the support layer 80 is not limited to have a structure not including a filler and may include a filler.

### 1.8 Resin Layer

The resin layer 90 is arranged, as depicted in FIG. 2 and FIG. 3, between the wiring portion 71 of the wiring layer 70 and the outer shield layer 30. The resin layer 90 has electrical insulation properties. The resin layer 90 is an insulator for insulating the wiring portion 71 and the outer shield layer 30.

The material of the resin layer 90 is, for example, synthetic resin such as epoxy resin or polyimide.

### 2 Effects

The acoustic wave device 10 according to the first embodiment includes the substrate 20, the outer connection electrode 40, and the outer shield layer 30. The substrate 20 has the first principal surface and the second principal surface that are mutually opposed, and the side surfaces connecting the first principal surface and the second principal surface together. The outer connection electrode 40 is arranged on the first principal surface 201 of the substrate 20. The outer shield layer 30 is arranged on the side surfaces 203 of the substrate 20. The tip surface 402 of the outer connection electrode 40 is exposed. With this, in the acoustic wave device 10 according to the first embodiment, in the module where a plurality of components including the acoustic wave device are arranged, the outer shield layer 30 functions as a shielding member between the acoustic wave device 10 and another component and between two other components. Furthermore, in the acoustic wave device 10, since the outer connection electrode 40 is directly in contact with the electrode of the mount substrate of the module, the height of the acoustic wave device 10 can be reduced.

Also, the acoustic wave device 10 according to the first embodiment further includes the cover layer 50. The cover layer 50 has the third principal surface 502 and the fourth principal surface 501 that are mutually opposed. The third principal surface 502 of the cover layer 50 is opposed to the first principal surface 201 of the substrate 20. The fourth principal surface 501 of the cover layer 50 is exposed. The tip surface 402 of the outer connection electrode 40 is arranged so as to be flush with the fourth principal surface 501 of the cover layer 50. With this, in the acoustic wave device 10 according to the first embodiment, in the module including the acoustic wave device 10, the acoustic wave device 10 and the mount substrate of the module can be brought close to each other in distance. Therefore, the height of the module including the acoustic wave device 10 can be easily reduced.

### Second Embodiment

### 1 Acoustic Wave Device

In an acoustic wave device 10a according to a second embodiment, a positional relation between the tip surface 402 of the plurality of outer connection electrodes 40 and the fourth principal surface 501 of the cover layer 50 is different from that of the acoustic wave device 10 according to the first embodiment.

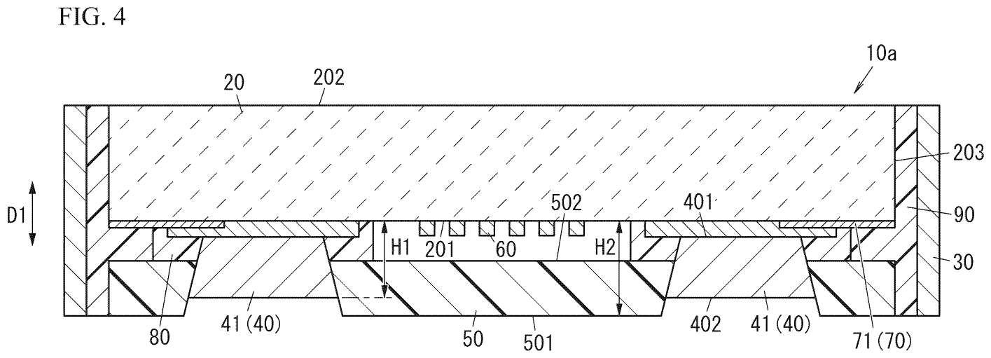

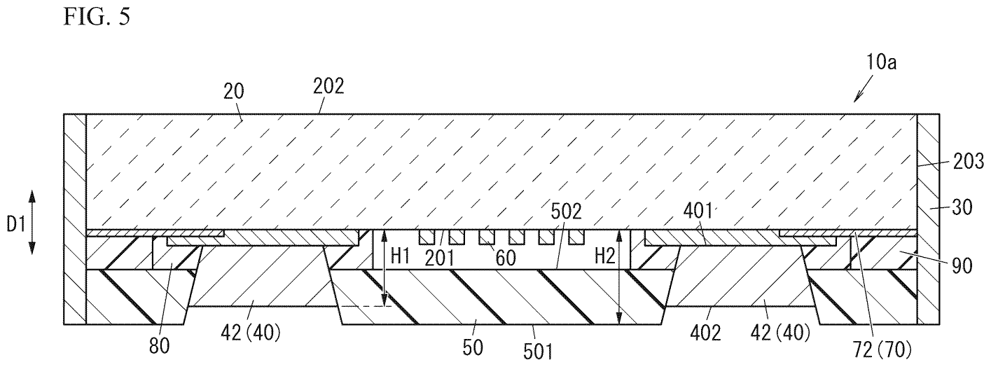

In the acoustic wave device 10a according to the second embodiment, as depicted in FIG. 4 and FIG. 5, a distance H1 in the first direction D1 between the tip surface 402 of the outer connection electrode 40 and the first principal surface 201 of the substrate 20 is shorter than a distance H2 in the first direction D1 between the fourth principal surface 501 of the cover layer 50 and the first principal surface 201 of the substrate 20.

More specifically, as depicted in FIG. 4 and FIG. 5, the outer connection electrode 40 does not penetrate through the cover layer 50, and the tip surface 402 of the outer connection electrode 40 is exposed from the fourth principal surface 501 of the cover layer 50. With this, when the acoustic wave device 10a is arranged on the mount substrate of the module, a distance between the fourth principal surface 501 of the cover layer 50 of the acoustic wave device 10a and the principal surface where the acoustic wave device 10a of the mount substrate of the module is arranged is further shortened.

### 2 High Frequency Module

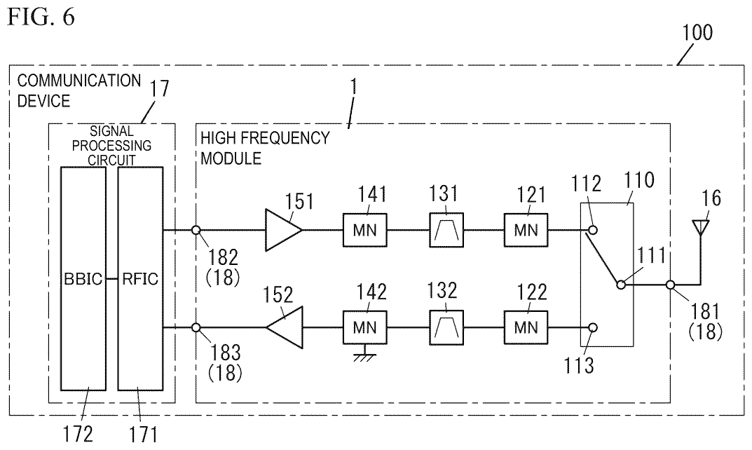

A high frequency module 1 according to the second embodiment is, as depicted in FIG. 6, used for, for example, a communication device 100. The communication device 100 is, for example, a cellular phone such as a smartphone. Note that the communication device 100 is not limited to a cellular phone and may be, for example, a wearable terminal such as a smartwatch, or the like. The high frequency module 1 is, for example, a module capable of supporting, for example, fourth generation mobile communication (4G) standards, fifth generation mobile communication (5G) standards, or the like. The 4G standards are, for example, Third Generation Partnership Project (3GPP; registered trademark) Long Term Evolution (LTE; registered trademark) standards. The 5G standards are, for example, 5G New Radio (NR).

### 2.1 High Frequency Module Circuit Structure

In the following, the circuit structure of the high frequency module 1 according to the second embodiment is described by using FIG. 6.

The high frequency module 1 according to the second embodiment includes, as depicted in FIG. 6, a plurality of outer connection terminals 18, a switch 110, a first matching circuit 121, a second matching circuit 122, a transmission filter 131, a reception filter 132, a third matching circuit 141, a fourth matching circuit 142, a power amplifier 151, and a low noise amplifier 152. The plurality of outer connection terminals 18 include an antenna terminal 181, a signal output terminal 182, and a signal input terminal 183. In the high frequency module 1, the first matching circuit 121, the transmission filter 131, the third matching circuit 141, and the power amplifier 151 are included in a transmission path. In the high frequency module 1, the second matching circuit 122, the reception filter 132, the fourth matching circuit 142, and the low noise amplifier 152 are included in a reception path.

### 2.1.1 Power Amplifier

The power amplifier 151 is an amplifier that amplifies a transmission signal. The power amplifier 151 has an input terminal (not depicted) and an output terminal (not depicted). The input terminal of the power amplifier 151 is connected via the signal output terminal 182 to the signal processing circuit 17. The output terminal of the power amplifier 151 is connected via the third matching circuit 141 to the transmission filter 131.

### 2.1.2 Transmission Filter

The transmission filter 131 is a filter that lets a transmission signal pass therethrough. The transmission filter 131 is, for example, an acoustic wave filter including a plurality of series arm resonators and a plurality of parallel arm resonators. The acoustic wave filter is, for example, a surface acoustic wave (SAW) filter using surface acoustic waves. The transmission filter 131 has an input terminal (not depicted) and an output terminal (not depicted). The input terminal of the transmission filter 131 is connected via the third matching circuit 141 to the output terminal of the power amplifier 151. The output terminal of the transmission filter 131 is connected via the first matching circuit 121 to the switch 110.

### 2.1.3 Low Noise Amplifier

The low noise amplifier 152 is an amplifier that amplifies a reception signal. The low noise amplifier 152 has an input terminal (not depicted) and an output terminal (not depicted). The input terminal of the low noise amplifier 152 is connected via the signal input terminal 183 to the signal processing circuit 17. The output terminal of the low noise amplifier 152 is connected via the fourth matching circuit 142 to the reception filter 132.

### 2.1.4 Reception Filter

The reception filter 132 is a filter that lets a reception signal pass therethrough. The reception filter 132 is, for example, an acoustic wave filter including a plurality of series arm resonators and a plurality of parallel arm resonators. The acoustic wave filter is, for example, a SAW filter using surface acoustic waves. The reception filter 132 has an input terminal (not depicted) and an output terminal (not depicted). The input terminal of the reception filter 132 is connected via the second matching circuit 122 to the switch 110. The output terminal of the reception filter 132 is connected to the output terminal of the low noise amplifier 152 via the fourth matching circuit 142.

### 2.1.5 Switch

The switch 110 switches filters connected to the antenna terminal 181 from among the transmission filter 131 and the reception filter 132. That is, the switch 110 is a switch for connecting either one of a reception path and a transmission path to the antenna terminal 181. The switch 110 has a common terminal 111 and a plurality of (two in the depicted example) selection terminals 112 and 113. The common terminal 111 is connected to the antenna terminal 181. The selection terminal 112 is connected via the first matching circuit 121 to the transmission filter 131. The selection terminal 113 is connected via the second matching circuit 122 to the reception filter 132. ps 2.1.6 Matching Circuit

The first matching circuit 121 is a circuit for impedance matching between the output terminal of the transmission filter 131 and the selection terminal 112 of the switch 110. The first matching circuit 121 includes at least one of one or more capacitors and one or more inductors.

The second matching circuit 122 is a circuit for impedance matching between the selection terminal 113 of the switch 110 and the input terminal of the reception filter 132. The second matching circuit 122 includes at least one of one or more capacitors and one or more inductors.

The third matching circuit 141 is a circuit for impedance matching between the output terminal of the power amplifier 151 and the input terminal of the transmission filter 131. The third matching circuit 141 includes at least one of one or more capacitors and one or more inductors.

The fourth matching circuit 142 is a circuit for impedance matching between the output terminal of the reception filter 132 and the input terminal of the low noise amplifier 152. The fourth matching circuit 142 includes at least one of one or more capacitors and one or more inductors. Note that while the fourth matching circuit 142 is grounded in FIG. 6, the fourth matching circuit 142 does not have to be grounded.

### 2.2 High Frequency Module Structure

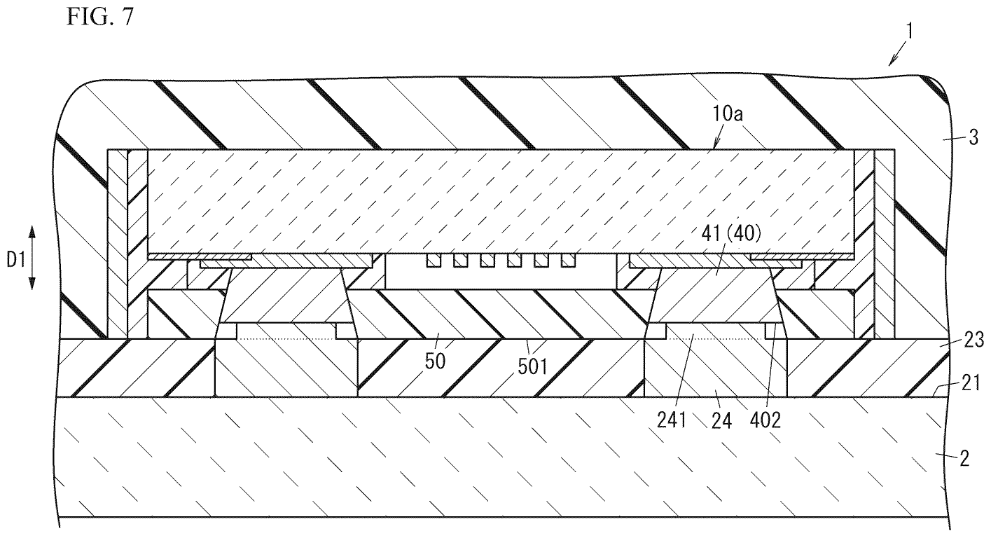

The high frequency module 1 includes, as depicted in FIG. 7, a mount substrate 2, the acoustic wave device 10a, and a resin layer 3. The acoustic wave device 10a includes, for example, the transmission filter 131.

The mount substrate 2 has, as depicted in FIG. 7, a principal surface 21. On the principal surface 21 of the mount substrate 2, the acoustic wave device 10a is arranged.

The mount substrate 2 is, for example, a multilayer substrate including a plurality of dielectric layers and a plurality of conductive layers. The plurality of dielectric layers and the plurality of conductive layers are laminated in the first direction D1. The plurality of conductive layers are formed in a predetermined pattern defined for each layer. The plurality of conductive layers each include one or plurality of conductor portions on one plane orthogonal to the first direction D1. The material of each conductive layer is, for example, copper. The mount substrate 2 is, for example, a high temperature co-fired ceramics (HTCC) board. The mount substrate 2 is not limited to a resin multilayer substrate and may be, for example, a low temperature co-fired ceramics (LTCC) board, printed wiring board, or resin multilayer substrate.

Also, the mount substrate 2 is not limited to a HTCC board and may be, for example, a wiring structure. The wiring structure is, for example, a multilayer structure. The multilayer structure includes at least one insulating layer and at least one conductive layer. The insulating layer is formed in a predetermined pattern. When a plurality of insulating layers are provided, the plurality of insulating layers are formed in a predetermined pattern defined for each layer. The conductive layer is formed in a predetermined pattern that is different from the predetermined pattern of the insulating layer. When a plurality of conductive layers are provided, the plurality of conductive layers are formed in a predetermined pattern defined for each layer. The conductive layer may include one or plurality of rewiring portions. In the wiring structure, a first surface of two mutually-opposed surfaces in a thickness direction of the multilayer structure is the principal surface 21 of the mount substrate 2. The wiring structure may be, for example, an interposer. The interposer may be an interposer using a silicone substrate or a substrate configured by multilayering.

Also, on the principal surface 21 of the mount substrate 2, an insulating layer 23 and a plurality of electrodes 24 are arranged.

The insulating layer 23 has electrical insulation properties. The insulating layer 23 is, for example, a solder resist. The insulating layer 23 covers, for example, a portion of the principal surface 21 of the mount substrate 2 other than the plurality of electrodes 24.

The plurality of electrodes 24 are connected to a plurality of outer connection electrodes 40 of the acoustic wave device 10a in a one-to-one correspondence. The plurality of outer connection electrodes 40 are each directly in contact with each of the plurality of electrodes 24. “The plurality of outer connection electrodes 40 are each directly in contact with each of the plurality of electrodes 24” means that at least part of the outer connection electrodes 40 and at least part of the electrodes 24 are directly in contact. That is, the outer connection electrode 40 and the electrode 24 may be jointed by soldering or the like as long as a portion is present where the outer connection electrode 40 and the electrode 24 are in contact not via soldering or the like. Of the plurality of electrodes 24, the electrode 24 connected to the second connection electrode 42 is grounded via the mount substrate 2. With this, the shielding effect of the outer shield layers 30 is improved.

The plurality of electrodes 24 each include a land electrode and a convex portion 241 arranged on the land electrode. The convex portion 241 is formed by, for example, plating a metal material on the land electrode. This facilitates the connection between the plurality of electrodes 24 and the plurality of outer connection electrodes 40 of the acoustic wave device 10b.

### 3 Communication Device

The communication device 100 includes, as depicted in FIG. 6, the high frequency module 1, a signal processing circuit 17, and an antenna 16.

The antenna 16 is connected to the antenna terminal 181 of the high frequency module 1. The antenna 16 has a transmitting function of emitting a transmission signal outputted from the high frequency module 1 as a radio wave and a receiving function of receiving a reception signal from outside as a radio wave for output to the high frequency module 1.

The signal processing circuit 17 includes a RF signal processing circuit 171 and a baseband signal processing circuit 172. The signal processing circuit 17 processes signals passing through the high frequency module 1. More specifically, the signal processing circuit 17 processes a transmission signal and a reception signal.

The RF signal processing circuit 171 is, for example, a radio frequency integrated circuit (RFIC). The RF signal processing circuit 171 performs signal processing on high frequency signals.

The RF signal processing circuit 171 performs signal processing, such as up-conversion, on a transmission signal transmitted from the baseband signal processing circuit 172 and amplifies the resultant signal, and outputs the transmission signal subjected to the signal processing to the high frequency module 1. Also, the RF signal processing circuit 171 amplifies a reception signal outputted from the high frequency module 1 and performs signal processing, such as down-conversion, on the resultant signal, and outputs the reception signal subjected to the signal processing to the baseband signal processing circuit 172.

The baseband signal processing circuit 172 is, for example, a baseband integrated circuit (BBIC). The baseband signal processing circuit 172 performs predetermined signal processing on a transmission signal from outside the signal processing circuit 17. The reception signal processed at the baseband signal processing circuit 172 is used as, for example, an image signal for image display or a voice signal for conversation.

Also, the RF signal processing circuit 171 further has a function as a control unit that controls a connection of the switch 110 included in the high frequency module 1 based on transmission or reception of a high frequency signal (transmission signal, reception signal). Specifically, the RF signal processing circuit 171 switches the connection of switch 110 in the high frequency module 1 by a control signal (not depicted). Note that the control unit may be provided outside the RF signal processing circuit 171 and, for example, may be provided in the high frequency module 1 or the baseband signal processing circuit 172.

### 4 Effects

The acoustic wave device 10a according to the second embodiment further includes the cover layer 50. The cover layer 50 has the third principal surface 502 and the fourth principal surface 501 that are mutually opposed. The third principal surface 502 of the cover layer 50 is opposed to the first principal surface 201 of the substrate 20. The fourth principal surface 501 of the cover layer 50 is exposed. The distance H1 in the first direction D1 between the tip surface 402 of the outer connection electrode 40 and the first principal surface 201 of the substrate 20 is shorter than the distance H2 in the first direction D1 between the fourth principal surface 501 of the cover layer 50 and the first principal surface 201 of the substrate 20. With this, according to the acoustic wave device 10a of the second embodiment, the height of the high frequency module including the acoustic wave device 10a can be easily further reduced.

The high frequency module 1 according to the second embodiment includes the acoustic wave device 10a and the mount substrate 2. On the mount substrate 2, the acoustic wave device 10a is arranged. With this, in the high frequency module 1 according to the second embodiment, the acoustic wave device 10a and the mount substrate 2 can be brought closer in distance. Therefore, the height of the high frequency module 1 can be easily reduced.

The communication device 100 according to the second embodiment includes the high frequency module 1 and the signal processing circuit 17 connected to the high frequency module 1. With this, according to the communication device 100 of the second embodiment, in the high frequency module 1, the outer shield layer 30 functions as a shielding member between the acoustic wave device 10a and another component and between two other components. Furthermore, since the acoustic wave device 10a is arranged on the high frequency module 1 in a state in which the outer connection electrode 40 is directly in contact with the electrode 24 of the mount substrate 2, the height of the acoustic wave device 10a can be reduced in the high frequency module 1.

### Third Embodiment

### 1 Structure

The high frequency module 1 according to a third embodiment includes, for example, an acoustic wave device 10b. In the acoustic wave device 10b, a distance in the first direction D1 between the tip surface 402 of the outer connection electrode 40 and the first principal surface 201 of the substrate 20 is longer than a distance in the first direction D1 between the third principal surface 502 of the cover layer 50 and the first principal surface 201 of the substrate 20. More specifically, a difference between the distance in the first direction D1 between the tip surface 402 of the outer connection electrode 40 and the first principal surface 201 of the substrate 20 and the distance in the first direction D1 between the third principal surface 502 of the cover layer 50 and the first principal surface 201 of the substrate 20 is shorter than or equal to 35 μm.

Also, in the high frequency module 1 according to the third embodiment, the electrode 24 of the mount substrate 2 is, for example, a land electrode. The thickness of the electrode 24 in the first direction D1 is less than the thickness of the insulating layer 23 in the first direction D1.

With the above, in the acoustic wave device 10b, the connectivity between the outer connection electrode 40 and the electrode 24 of the mount substrate 2 is improved, compared to the acoustic wave device 10 and the acoustic wave device 10a. Also, the thickness of the high frequency module 1 in the first direction D1 can be reduced.

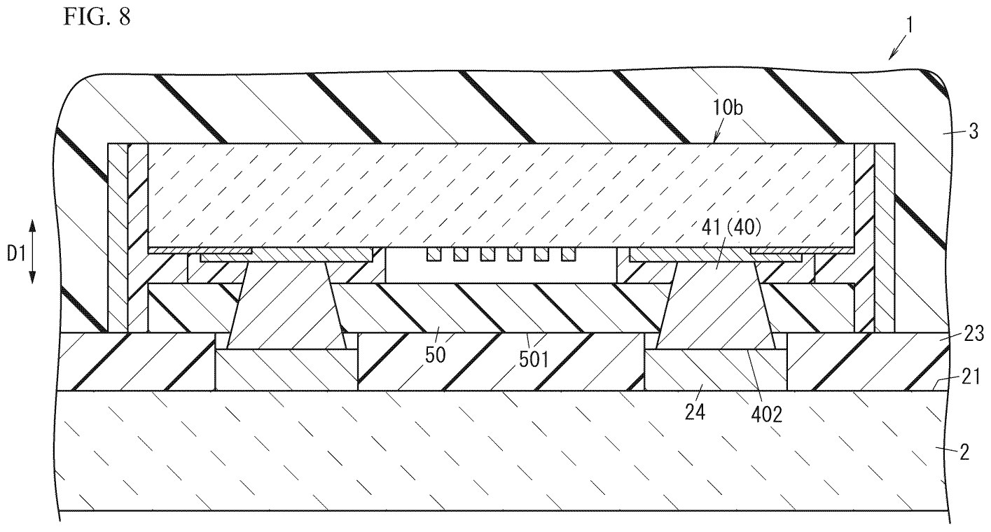

Also, in the high frequency module 1 according to the third embodiment, as depicted in FIG. 8, the acoustic wave device 10b is in contact with the insulating layer 23 in the first direction D1. With this, according to the high frequency module 1 of the third embodiment, the thickness of the high frequency module 1 in the first direction D1 can be reduced. Also, since the acoustic wave device 10b is in contact with the insulating layer 23 in the first direction D1 in the high frequency module 1, the acoustic wave device 10b is stably arranged on the mount substrate 2.

### 2 Effects

In the high frequency module 1 according to the third embodiment, the mount substrate 2 includes the insulating layer 23 arranged on the principal surface 21 where the acoustic wave device 10b is arranged. The acoustic wave device 10b is in contact with the insulating layer 23 of the mount substrate 2 in the first direction D1. With this, according to the high frequency module 1 of the third embodiment, close contactness of the acoustic wave device 10b with respect to the mount substrate 2 is improved. Therefore, the height of the high frequency module 1 can be reduced.

### Modification

The high frequency module 1 according to a modification of the third embodiment includes the acoustic wave device 10.

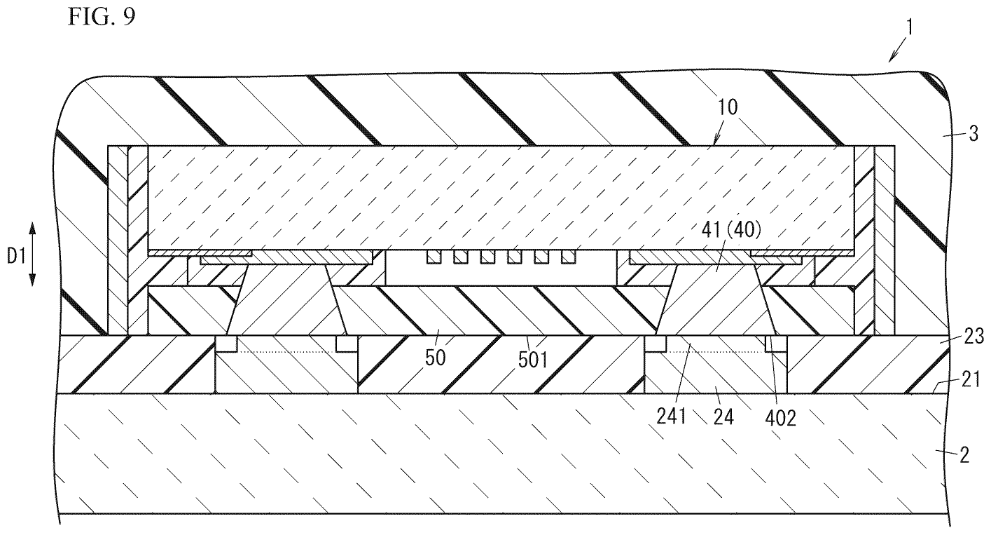

In the high frequency module 1 according to the modification of the third embodiment, as depicted in FIG. 9, the electrode 24 has the convex portion 241 in addition to the land electrode depicted in FIG. 8. With this, the thickness of the high frequency module 1 in the first direction D1 can be reduced, and the connection between the outer connection electrode 40 of the acoustic wave device 10 and the electrode 24 of the mount substrate 2 is ensured.

Similarly, the high frequency module 1 according to the third embodiment may include the acoustic wave device 10a. Specifically, the high frequency module 1 according to the modification of the third embodiment may have a structure similar to that of the high frequency module 1 depicted in FIG. 9, with the convex portion 241 of the electrode 24 being larger.

Also, with the above-described structure, as with the high frequency module according to the third embodiment, close contactness of the acoustic wave device 10 or 10a with respect to the mount substrate 2 is improved. Therefore, the height of the high frequency module 1 can be reduced.

### Fourth Embodiment

### 1 Structure

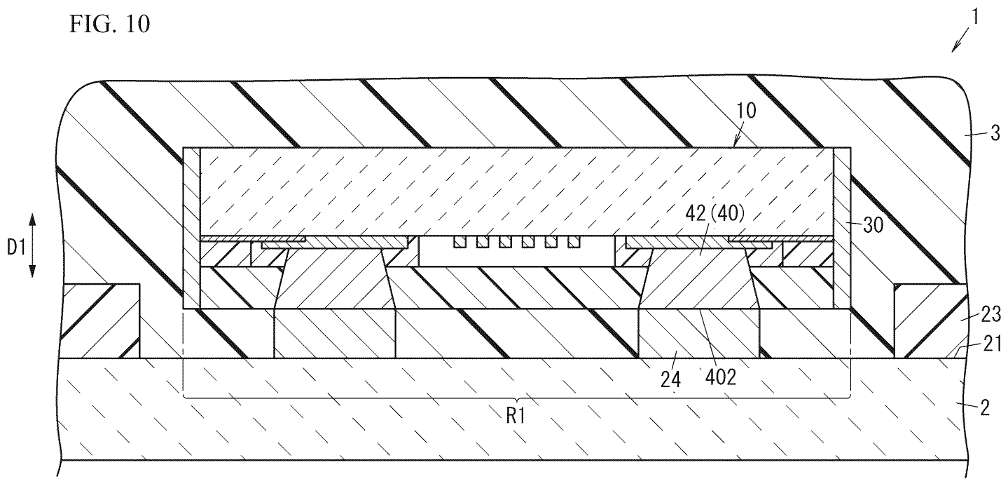

The high frequency module 1 according to a fourth embodiment includes, for example, the acoustic wave device 10. In the high frequency module 1 according to the fourth embodiment, as depicted in FIG. 10, the insulating layer 23 is not present in an arrangement area R1 of the principal surface 21 of the mount substrate 2.

More specifically, in the high frequency module 1 according to the fourth embodiment, as depicted in FIG. 10, the insulating layer 23 is not present in the arrangement area R1 of the principal surface 21 of the mount substrate 2. Here, “the arrangement area R1 of the principal surface 21 of the mount substrate 2” refers to an area of the principal surface 21 of the mount substrate 2 overlapping the acoustic wave device 10b in plan view from the first direction D1.

In the high frequency module 1 according to the fourth embodiment, since the acoustic wave device 10 and the insulating layer 23 are not in contact with each other, part of the resin layer 3 is formed between the acoustic wave device 10 and the principal surface 21 of the mount substrate 2. Therefore, the connection between the outer connection electrode 40 of the acoustic wave device 10 and the electrode 24 of the mount substrate 2 is ensured.

### 2 Effects

In the high frequency module 1 according to the fourth embodiment, the mount substrate 2 includes the insulating layer 23 arranged on the principal surface 21 where the acoustic wave device 10 is arranged. In the arrangement area R1 of the principal surface 21 of the mount substrate 2, the insulating layer 23 is not present. The arrangement area R1 of the principal surface 21 of the mount substrate 2 overlaps the acoustic wave device 10 in plan view from the first direction D1. With this, in the high frequency module 1 according to the fourth embodiment, the distance in the first direction D1 between the acoustic wave device 10 and the mount substrate 2 can be reduced. Therefore, the height of the high frequency module 1 can be reduced.

### First Modification

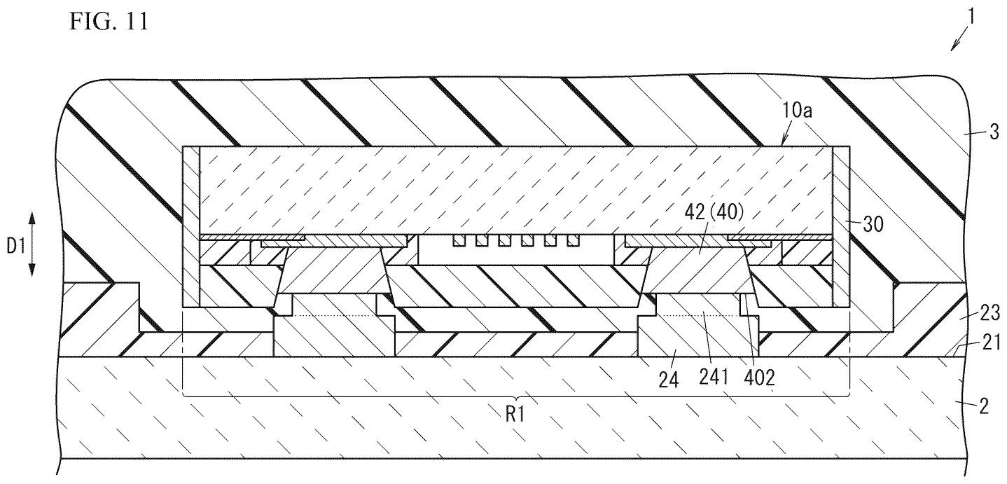

In the high frequency module 1 according to a first modification of the fourth embodiment, as depicted in FIG. 11, on the principal surface 21 of the mount substrate 2, the thickness of the insulating layer 23 in the first direction D1 is not uniform between the arrangement area R1 and areas other than the arrangement area R1.

More specifically, in the high frequency module 1 according to the fourth embodiment, as depicted in FIG. 11, in the arrangement area R1 of the principal surface 21 of the mount substrate 2, the thickness of the insulating layer 23 in the first direction D1 is less than the thickness of the insulating layer 23 other than the arrangement area R1 in the first direction D1. As with the above, also this structure can further reduce the height of the high frequency module 1. Note that while the high frequency module 1 has the acoustic wave device 10b in FIG. 11, the high frequency module 1 may include the acoustic wave device 10 or 10a.

In the high frequency module 1 according to the first modification of the fourth embodiment, the mount substrate 2 includes the insulating layer 23 arranged on the principal surface 21 where the acoustic wave device 10b is arranged. In the arrangement area R1 of the principal surface 21 of the mount substrate 2, the thickness of the insulating layer 23 in the first direction D1 is less than the thickness of the insulating layer 23 other than the arrangement area R1 in the first direction D1. With this, in the high frequency module 1 according to the first modification of the fourth embodiment, the distance in the first direction D1 between the acoustic wave device 10b and the mount substrate 2 can be reduced. Therefore, the height of the high frequency module 1 can be reduced.

### Second Modification

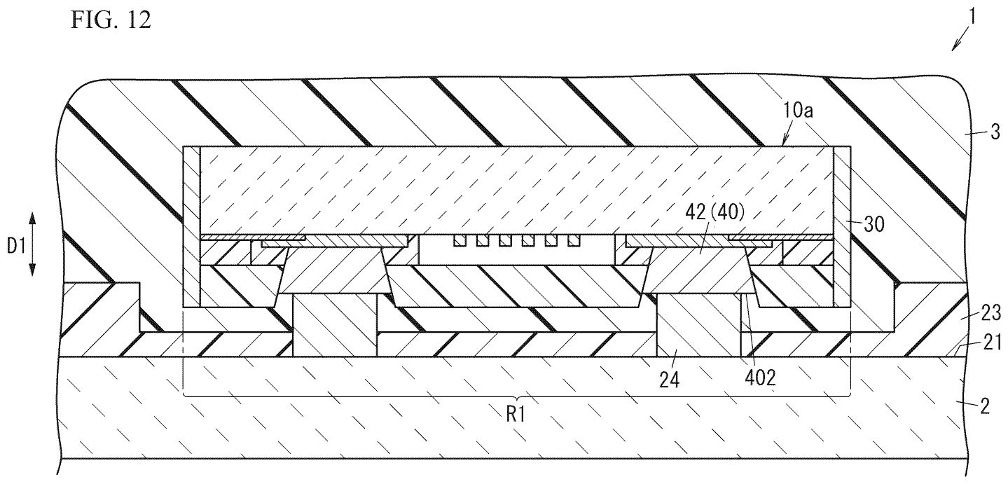

In the high frequency module 1 according to a second modification of the fourth embodiment, as with the first modification of the fourth embodiment, as depicted in FIG. 12, on the principal surface 21 of the mount substrate 2, the thickness of the insulating layer 23 in the first direction D1 is not uniform between the arrangement area R1 and areas other than the arrangement area R1.

More specifically, in the high frequency module 1 according to the fourth embodiment, as depicted in FIG. 12, in the arrangement area R1 of the principal surface 21 of the mount substrate 2, the thickness of the insulating layer 23 in the first direction D1 is less than the thickness of the insulating layer 23 other than the arrangement area R1 in the first direction D1. As with the above, also this structure can further reduce the height of the high frequency module 1. Note that in the high frequency module 1 depicted in FIG. 12, the electrode 24 does not have the convex portion 241, and the thickness of the electrode 24, which is a land electrode, in the first direction D1 is less than the thickness of the insulating layer 23 in the arrangement area R1 in the first direction D1. Here, the thickness of the electrode 24 in the first direction D1 may be equal to the thickness of the insulating layer 23 other than the arrangement area R1 in the first direction D1. In the high frequency module 1 according to the second modification of the fourth embodiment, as with the high frequency module 1 according to the first modification of the fourth embodiment, the height of the high frequency module 1 can be reduced.

### Fifth Embodiment

### 1 Structure

The high frequency module 1 according to a fifth embodiment has a structure similar to that of the high frequency module 1 according to the fourth embodiment. In the high frequency module 1 according to the fifth embodiment, the mount substrate 2 includes an electrode 25 on the principal surface 21. The electrode 25 is, for example, a land electrode, and is connected to the outer shield layer 30 of the acoustic wave device 10, 10a, or 10b. The electrode 25 corresponds to a second electrode of the present disclosure. The electrode 25 is connected, for example, via the mount substrate 2 to the ground.

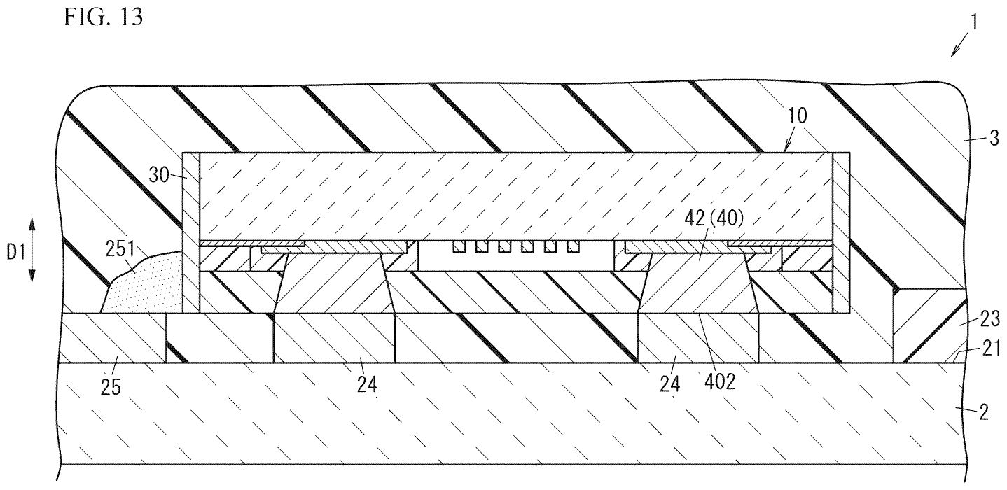

In the high frequency module 1 according to the fifth embodiment, as depicted in FIG. 13, the electrode 25 is arranged on the principal surface 21 of the mount substrate 2. The electrode 25 is connected to the outer shield layer 30 of the acoustic wave device 10. More specifically, the electrode 25 of the mount substrate 2 and the outer shield layer 30 of the acoustic wave device 10 are connected together by a solder piece 251. Note that the electrode 25 of the mount substrate 2 may have a frame shape along the outer periphery of the arrangement area R1. Also, the mount substrate 2 may include a plurality of electrodes 25 along the outer periphery of the arrangement area R1, and each of the plurality of electrodes 25 may be connected to the outer shield layer 30 of the acoustic wave device 10 by a plurality of solder pieces 251. With this, the outer shield layer 30 is connected to the ground not only by the second connection electrode 42 but also by the electrode 25. Thus, shieldability of the outer shield layer 30 can be improved.

### 2 Effects

In the high frequency module 1 according to the fifth embodiment, the mount substrate 2 has the electrode 24 connected to the outer connection electrode 40 and the electrode 25 connected to the outer shield layer 30 of the acoustic wave device 10. With this, in the high frequency module 1 according to the fifth embodiment, shieldability of the outer shield layer 30 of the acoustic wave device 10 can be improved.

### First Modification

The high frequency module 1 according to a first modification of the fifth embodiment has a structure similar to that of the high frequency module 1 according to the first modification of the fourth embodiment. The high frequency module 1 according to the first modification of the fifth embodiment has the electrode 25 connected to the outer shield layer 30 of the acoustic wave device 10.

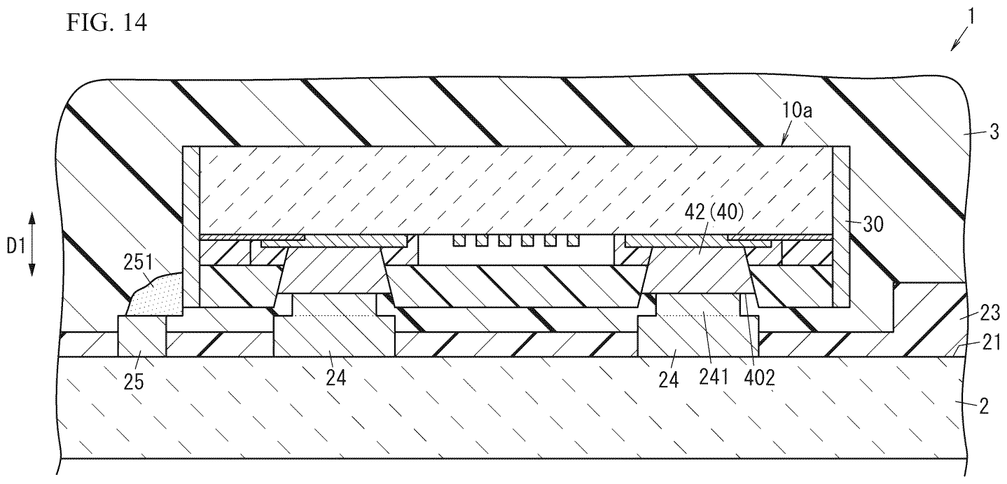

More specifically, as depicted in FIG. 14, in the high frequency module 1 according to the first modification of the fifth embodiment, the electrode 25 is arranged on the principal surface 21 of the mount substrate 2. The electrode 25 is connected to the outer shield layer 30 of the acoustic wave device 10. Also, with this structure, the outer shield layer 30 is connected to the ground not only by the second connection electrode 42 but also by the electrode 25. Thus, shieldability of the outer shield layer 30 is improved.

### Second Modification

The high frequency module 1 according to a second modification of the fifth embodiment has a structure similar to that of the high frequency module 1 according to the second modification of the fourth embodiment. The high frequency module 1 according to the first modification of the fifth embodiment has the electrode 25 connected to the outer shield layer 30 of the acoustic wave device 10.

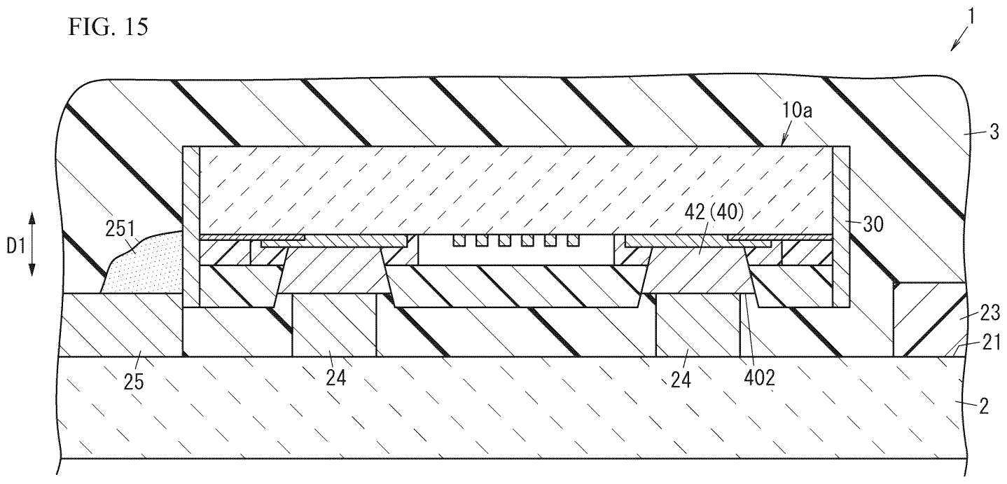

More specifically, as depicted in FIG. 15, in the high frequency module 1 according to the second modification of the fifth embodiment, the electrode 25 is arranged on the principal surface 21 of the mount substrate 2. The electrode 25 is connected to the outer shield layer 30 of the acoustic wave device 10. Also, with this structure, the outer shield layer 30 is connected to the ground not only by the second connection electrode 42 but also by the electrode 25. Thus, shieldability of the outer shield layer 30 is improved.

### Sixth Embodiment

### 1 Structure

In the high frequency module 1 according to a sixth embodiment, as with the high frequency module 1 according to the third embodiment, the acoustic wave device 10b is in contact with the insulating layer 23 in the first direction D1. In the high frequency module 1 according to the sixth embodiment, further in the arrangement area R1, a second area R12 in which the acoustic wave device 10b is in contact with the insulating layer 23 in the first direction D1 surrounds a first area R11 where the insulating layer 23 in the first direction D1 is thin or the insulating layer 23 is not present.

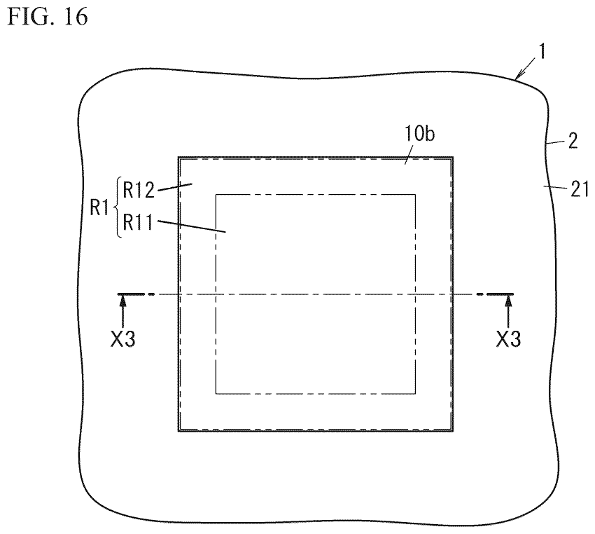

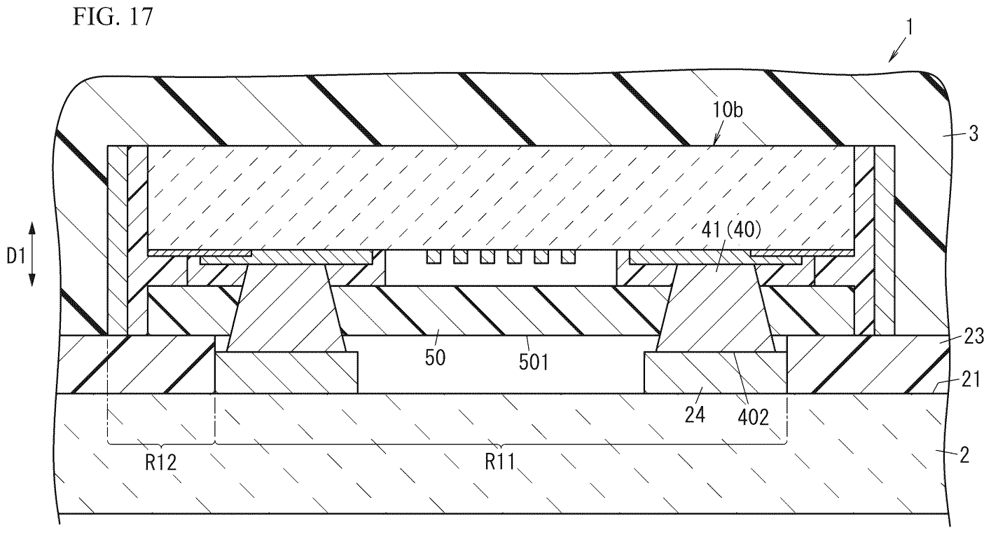

In the high frequency module 1 according to the sixth embodiment, as depicted in FIG. 16 and FIG. 17, in the arrangement area R1, the insulating layer 23 is not present in the first area R11. Note that the resin layer 3 is omitted in FIG. 16. Also, in the high frequency module 1 according to the sixth embodiment, as depicted in FIG. 16 and FIG. 17, in the arrangement area R1, the acoustic wave device 10b is in contact with the insulating layer 23 in the second area R12 in the first direction D1. Furthermore, as depicted in FIG. 16 and FIG. 17, the second area R12 surrounds the first area R11.

In the high frequency module 1 according to the sixth embodiment, in the second area R12, the acoustic wave device 10b is in contact with the insulating layer 23 in the first direction D1. Also, in the high frequency module 1 according to the sixth embodiment, the second area R12 surrounds the first area R11 in plan view from the first direction D1. Thus, it is possible to set a structure without having the resin layer 3 in the first area R11. With this, in the resin layer 3, it is possible to reduce stress in a direction of peeling off the mount substrate 2 and the acoustic wave device 10b to the first direction D1.

Also, in the high frequency module 1 according to the sixth embodiment, in the first area R11, it is possible to set a structure in which the thickness of the insulating layer 23 in the first direction D1 is less than the thickness of the insulating layer 23 in the second area R12 in the first direction D1. Also, according to this structure, in the second area R12, the acoustic wave device 10b is in contact with the insulating layer 23 in the first direction D1. Furthermore, in the high frequency module 1 according to the sixth embodiment, the second area R12 surrounds the first area R11 in plan view from the first direction D1. Therefore, the structure without having the resin layer 3 in the first area R11 can be easily set.

### 2 Effects

In the high frequency module 1 according to the sixth embodiment, the arrangement area R1 of the principal surface 21 of the mount substrate 2 overlapping the acoustic wave device 10b in plan view from the first direction D1 includes the first area R11 and the second area R12. In the first area R11, the thickness of the insulating layer 23 in the first direction D1 is less than the thickness of the insulating layer 23 in the second area R12 in the first direction D1 or the insulating layer 23 is not present. In the second area R12, the acoustic wave device 10b is in contact with the insulating layer 23 of the mount substrate 2 in the first direction D1. The second area R12 surrounds the first area R11. With this, in the high frequency module 1 according to the sixth embodiment, the acoustic wave device 10b is less prone to being peeled off from the mount substrate 2.

### Seventh Embodiment

### 1 Structure

In a high frequency module 1a according to a seventh embodiment, as with the high frequency module 1 according to the sixth embodiment, in the arrangement area R1, the second area R12 where an acoustic wave device 10c is in contact with the insulating layer 23 in the first direction D1 surrounds the first area R11 where the thickness of the insulating layer 23 in the first direction D1 is less than the second area R12 or the insulating layer 23 is not present. In the high frequency module 1a according to the seventh embodiment, furthermore, the acoustic wave device 10c does not have the cover layer 50.

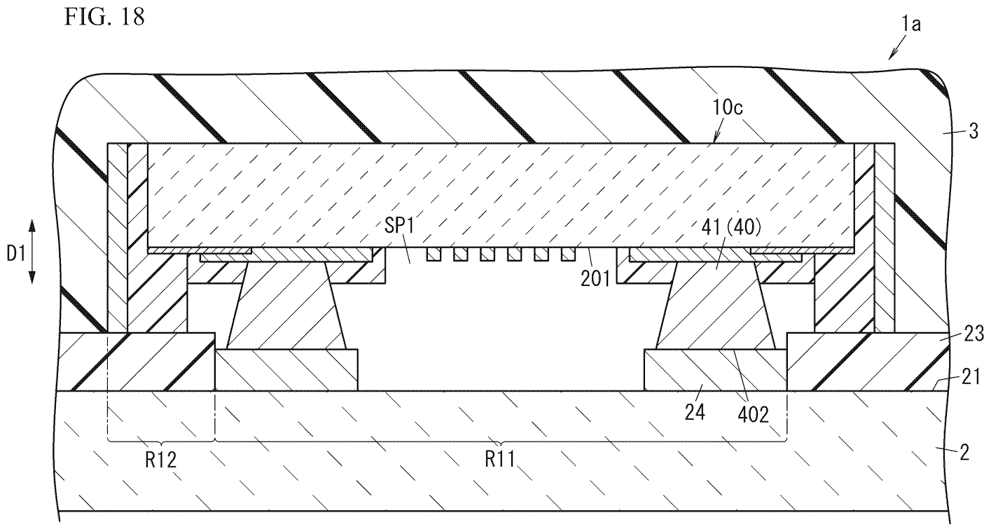

More specifically, in the high frequency module 1a according to the seventh embodiment, as depicted in FIG. 18, in the arrangement area R1, the insulating layer 23 is not present in the first area R11. Also, in the high frequency module 1a according to the seventh embodiment, as depicted in FIG. 18, in the arrangement area R1, the acoustic wave device 10b is in contact with the insulating layer 23 in the first direction D1 in the second area R12. Furthermore, as depicted in FIG. 18, the second area R12 surrounds the first area R11.

Also, in the high frequency module 1a according to the seventh embodiment, as depicted in FIG. 18, a hollow space SP1 interposed between the substrate 20 of the acoustic wave device 10c and the mount substrate 2 is formed. In plan view from the first direction D1, the hollow space SP1 overlaps the first area R11.

As described above, since the acoustic wave device 10b is in contact with the insulating layer 23 in the second area R12 in the first direction D1, even if the resin layer 3 is formed after the acoustic wave device 10c is mounted on the mount substrate 2, the resin layer 3 does not get into the hollow space SP1. Therefore, in the high frequency module 1a according to the seventh embodiment, the state in which the resin layer 3 is not present in the hollow space SP1 is kept. Therefore, in the high frequency module 1a according to the seventh embodiment, even if the acoustic wave device 10c does not have the cover layer 50, it is possible to keep the state in which the functional electrode 60 of the acoustic wave device 10c is arranged in the hollow space SP1.

Therefore, in the high frequency module 1a according to the seventh embodiment, since the acoustic wave device 10c does not have the cover layer 50, the height of the acoustic wave device 10c can be reduced. With this, the height of the high frequency module 1 can be reduced.

### 2 Effects

In the high frequency module 1a according to the seventh embodiment, the hollow space SP1 interposed between the substrate 20 of the acoustic wave device 10c and the mount substrate 2 is formed. In the plan view from the first direction D1, the hollow space SP1 overlaps the first area R11. With this, in the high frequency module 1 according to the seventh embodiment, the distance in the first direction D1 between the substrate 20 of the acoustic wave device 10c and the mount substrate 2 can be further reduced. Therefore, the height of the acoustic wave device 10c can be reduced, and the size of the high frequency module 1 can be reduced.

### Eighth Embodiment

### 1 Structure

The high frequency module 1 according to an eighth embodiment further includes a first component 4 and a second component 5. In plan view from the first direction D1, the acoustic wave device 10 is arranged between the first component 4 and the second component 5.

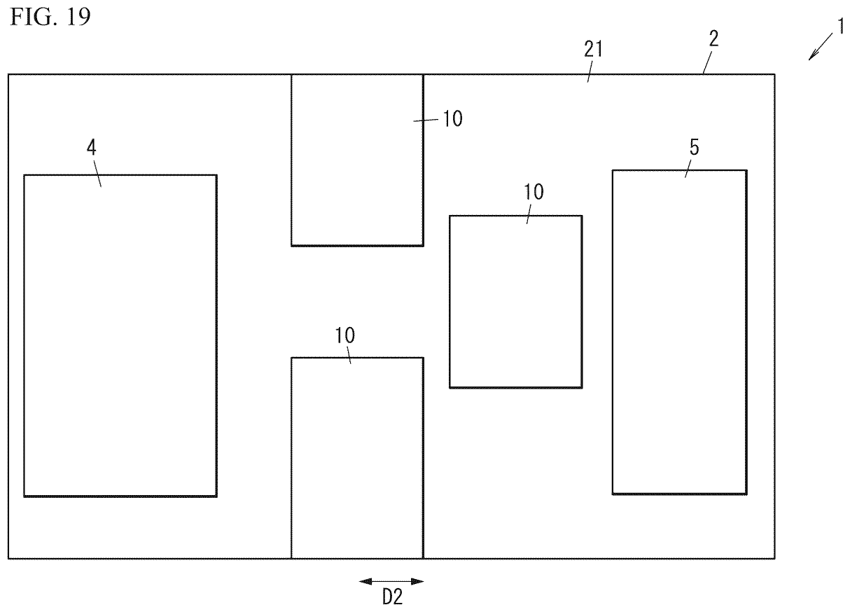

The high frequency module 1 according to the eighth embodiment includes, as depicted in FIG. 19, the first component 4 and the second component 5. The first component 4 includes, for example, the power amplifier 151. Also, the second component 5 includes, for example, the low noise amplifier 152.

Also, the high frequency module 1 according to the eighth embodiment includes, for example, as depicted in FIG. 19, a plurality of (three in FIG. 19) acoustic wave devices 10. The plurality of acoustic wave devices 10 include, for example, the transmission filter 131 and the reception filter 132. Also, in the high frequency module 1 according to the eighth embodiment, the plurality of acoustic wave devices 10 include, for example, a reception filter (not depicted in FIG. 7).

Furthermore, in the high frequency module 1 according to the eighth embodiment, in plan view from the first direction D1, the acoustic wave device 10 is arranged between the first component 4 and the second component 5. Here, “in plan view from the first direction D1, the acoustic wave device 10 is arranged between the first component 4 and the second component 5” means that the acoustic wave device 10 is arranged on a line segment connecting any point included in the first component 4 and any point included in the second component 5.

Still further, in the high frequency module 1 according to the eighth embodiment, in plan view from the first direction D1, any one of the plurality of acoustic wave devices 10 is arranged between the first component 4 and the second component 5. That is, at least one acoustic wave device 10 is arranged on a line segment connecting any point included in the first component 4 and any point included in the second component 5. More specifically, in plan view from the first direction D1, the first component 4, the plurality of acoustic wave devices 10, and the second component 5 are aligned in this sequence along a second direction D2. The plurality of acoustic wave devices 10 are aligned between the first component 4 and the second component 5 in a third direction D3 orthogonal to the second direction D2.

Still further, in the high frequency module 1 according to the eighth embodiment, when the second component 5 is viewed from the first component 4, the plurality of acoustic wave devices 10 are aligned without a gap. Here, “when the second component 5 is viewed from the first component 4, the plurality of acoustic wave devices 10 are aligned without a gap” means that, in plan view from a direction from the first component 4 toward the second component 5, the plurality of acoustic wave devices 10 are arranged so as not to form a gap. Specifically, in the high frequency module 1 according to the eighth embodiment, in plan view from the second direction D2, the plurality of acoustic wave devices 10 are arranged so as not to form a gap.

With this, in the high frequency module 1 according to the eighth embodiment, the isolation between the first component 4 and each of the plurality of acoustic wave devices 10 can be improved. Also, the isolation between the second component 5 and each of the plurality of acoustic wave devices 10 can be improved. Furthermore, the isolation between the first component 4 and the second component 5 can be improved.

### 2 Effects

The high frequency module 1 according to the eighth embodiment further includes the first component 4 and the second component 5. In plan view from the first direction D1, the acoustic wave device 10 is arranged between the first component 4 and the second component 5. With this, according to the high frequency module 1 of the eighth embodiment, the isolation between the first component 4 and the acoustic wave device 10, between the acoustic wave device 10 and the second component 5, and between the first component 4 and the second component 5 can be improved.

Also, the high frequency module 1 according to the eighth embodiment includes the plurality of acoustic wave devices 10. On a straight line connecting the first component 4 and the second component 5, any one acoustic wave device 10 among the plurality of acoustic wave devices 10 is arranged. When the second component 5 is viewed from the first component 4, the plurality of acoustic wave devices 10 are aligned without a gap. With this, according to the high frequency module 1 of the eighth embodiment, the isolation between the first component 4 and the acoustic wave device 10, between the acoustic wave device 10 and the second component 5, and between the first component 4 and the second component 5 can be improved. Furthermore, in the high frequency module 1, since the plurality of acoustic wave devices 10 are arranged between the first component 4 and the second component 5, the isolation between the first component 4 and the second component 5 is easily improved.

### Ninth Embodiment

### 1 Structure

The high frequency module 1 according to a ninth embodiment includes, as with the high frequency module 1 according to the eighth embodiment, the first component 4 and the second component 5. In plan view from the first direction D1, the plurality of acoustic wave devices 10 are arranged between the first component 4 and the second component 5. The plurality of acoustic wave devices 10 are in contact with each other.

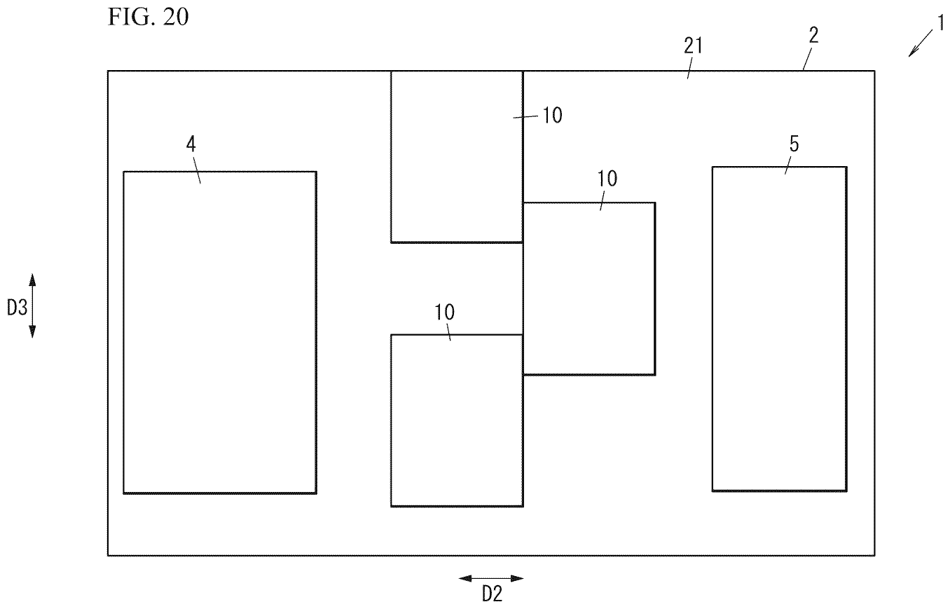

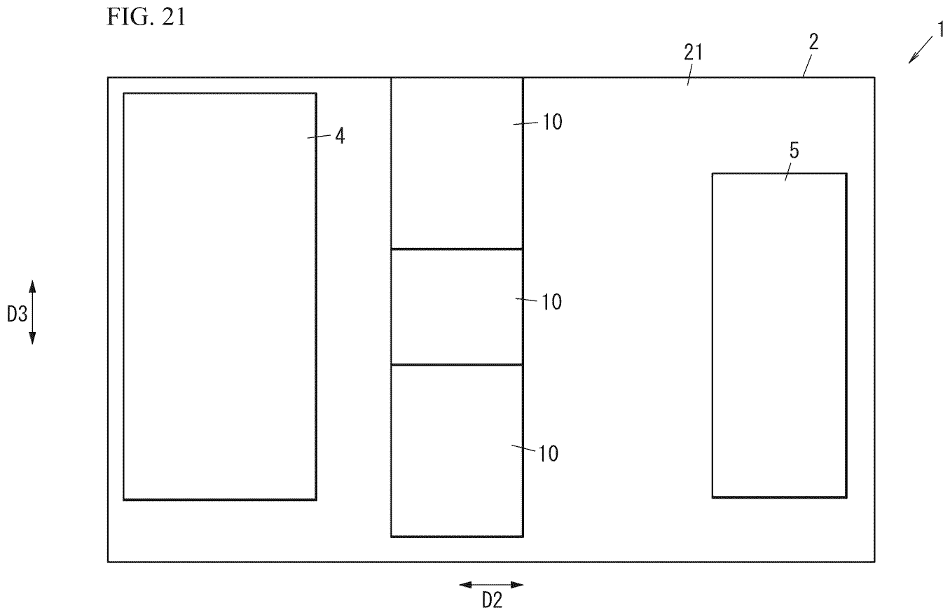

In the high frequency module 1 according to the ninth embodiment, as depicted in FIG. 20, the plurality of acoustic wave devices 10 are in contact with each other. More specifically, among the plurality of acoustic wave devices 10, the outer shield layer 30 of one acoustic wave device 10 and the outer shield layer 30 of another acoustic wave device 10 are in contact with each other. The one acoustic wave device 10 corresponds to a first acoustic wave device of the present disclosure. The other acoustic wave device 10 corresponds to a second acoustic wave device of the present disclosure. With this, in the high frequency module 1 according to the ninth embodiment, the isolation between the first component 4 and the second component 5 is further improved. In this case, for example, as depicted in FIG. 21, the plurality of acoustic wave devices 10 may be aligned on a straight line to the third direction D3.

### 2 Effects

In the high frequency module 1 according to the ninth embodiment, the plurality of acoustic wave devices 10 include a first acoustic wave device 10 and a second acoustic wave device 10. The outer shield layer 30 of the first acoustic wave device 10 is in contact with the outer shield layer 30 of the second acoustic wave device 10. With this, in the high frequency module 1 according to the ninth embodiment, the effect of improving the isolation between the first component 4 and the second component 5 by the outer shield layer 30 of the acoustic wave device 10 is further increased.

### First Modification

In the high frequency module 1 according to the ninth embodiment, as depicted in FIG. 20, the plurality of acoustic wave devices 10 are in contact with each other. More specifically, the plurality of acoustic wave devices 10 are aligned on a straight line to the third direction D3. Also, with this structure, the effect of improving the isolation between the first component 4 and the second component 5 by the outer shield layer 30 of the acoustic wave device 10 is further increased.

### Other Modifications

While the high frequency module 1 according to the second embodiment includes the acoustic wave device 10a, the high frequency module 1 may include the acoustic wave device 10 or the acoustic wave device 10b in place of or in addition to the acoustic wave device 10a.

Also, the high frequency module 1 according to the eighth or ninth embodiment may include the acoustic wave device 10a, 10b, or 10c in place of the acoustic wave device 10.

Furthermore, in the communication device 100 according to the second embodiment, the high frequency module 1 included in the communication device 100 may include the acoustic wave device 10 or the acoustic wave device 10b in place of or in addition to the acoustic wave device 10a.

Still further, the communication device 100 according to the second embodiment may include the high frequency module 1 according to any of the third to eighth embodiments.

Still further, the high frequency module 1 according to the second to ninth embodiments may have an outer shield layer covering the resin layer 3. Here, the outer shield layer of the high frequency module 1 may be in contact with the outer shield layer 30 of the acoustic wave device 10. This allows reduction in size of the high frequency module 1 and improvement in the shielding effect of the outer shield layer of the high frequency module 1.

### Aspects

An acoustic wave device (10 to 10c) according to a first aspect includes a substrate (20), an outer connection electrode (40), and an outer shield layer (30). The substrate (20) has a first principal surface (201) and a second principal surface (202) that are mutually opposed, and side surfaces (203) connecting the first principal surface (201) and the second principal surface (202) together. The outer connection electrode (40) is arranged on the first principal surface (201) of the substrate (20). The outer shield layer (30) is arranged on the side surfaces (203) of the substrate (20). A tip surface (402) of the outer connection electrode (40) is exposed.

According to the acoustic wave device (10 to 10c) with the above-described structure, in the module where a plurality of components including the acoustic wave device (10 to 10c) are arranged, the outer shield layer (30) functions as a shielding member between the acoustic wave device (10 to 10c) and another component and between two other components. Furthermore, in the acoustic wave device (10 to 10c), since the outer connection electrode (40) is directly in contact with the electrode of the mount substrate of the module, the height of the acoustic wave device (10 to 10c) can be reduced in the high frequency module (1).

The acoustic wave device (10) according to a second aspect further includes a cover layer (50), in the first aspect. The cover layer (50) has a third principal surface (502) and a fourth principal surface (501) that are mutually opposed. The third principal surface (502) of the cover layer (50) is opposed to the first principal surface (201) of the substrate (20). The fourth principal surface (501) of the cover layer (50) is exposed. The tip surface (402) of the outer connection electrode (40) is arranged so as to be flush with the fourth principal surface (501) of the cover layer (50).

According to the acoustic wave device (10) with the above-described structure, in the module including the acoustic wave device (10), the acoustic wave device (10) and the mount substrate of the module can be brought close to each other in distance. Therefore, the height of the module including the acoustic wave device (10) can be easily reduced.

The acoustic wave device (10) according to a third aspect further includes a cover layer (50), in the first aspect. The cover layer (50) has a third principal surface (502) and a fourth principal surface (501) that are mutually opposed. The third principal surface (502) of the cover layer (50) is opposed to the first principal surface (201) of the substrate (20). The fourth principal surface (501) of the cover layer (50) is exposed. A distance (H1) in a first direction (D1) between the tip surface (402) of the outer connection electrode (40) and the first principal surface (201) of the substrate (20) is shorter than a distance (H2) in the first direction (D1) between the fourth principal surface (501) of the cover layer (50) and the first principal surface (201) of the substrate (20). The first direction (D1) is a thickness direction of the substrate (20).

According to the acoustic wave device (10) with the above-described structure, the height of the high frequency module (1) including the acoustic wave device (10) can be easily further reduced.

A high frequency module (1; 1a) according to a fourth aspect includes the acoustic wave device (10 to 10c) according to any one of the first to third aspects and a mount substrate (2). On the mount substrate (2), the acoustic wave device (10 to 10c) is arranged.

According to the high frequency module (1; 1a) with the above-described structure, the acoustic wave device (10 to 10c) and the mount substrate (2) can be brought closer in distance. Therefore, the height of the high frequency module 1 can be easily reduced.

In the high frequency module (1; 1a) according to a fifth aspect, in the high frequency module (1; 1a) according to the fourth aspect, the mount substrate (2) includes an insulating layer (23) arranged on a principal surface (21) where the acoustic wave device (10 to 10c) is arranged. The acoustic wave device (10 to 10c) is in contact with the insulating layer (23) of the mount substrate (2) in a first direction (D1). The first direction (D1) is a thickness direction of the substrate (20).

According to the high frequency module (1; 1a) with

the above-described structure, close contactness of the acoustic wave device (10 to 10c) with respect to the mount substrate (2) is improved. Therefore, the height of the high frequency module (1; 1a) can be reduced.

In the high frequency module (1; 1a) according to a sixth aspect, in the fifth aspect, an arrangement area (R1) of the principal surface (21) of the mount substrate (2) overlapping the acoustic wave device (10 to 10c) in plan view from the first direction (D1) includes a first area (R11) and a second area (R12). In the first area (R11), a thickness of the insulating layer (23) in the first direction (D1) is less than a thickness of the insulating layer (23) in the second area (R12) in the first direction (D1) or the insulating layer (23) is not present. In the second area (R12), the acoustic wave device (10 to 10c) is in contact with the insulating layer (23) of the mount substrate (2) in the first direction (D1). The second area (R12) surrounds the first area (R11).

According to the high frequency module (1; 1a) with the above-described aspect, the acoustic wave device (10 to 10c) is less prone to being peeled off from the mount substrate (2).

In the high frequency module (1a) according to a seventh aspect, in the sixth aspect, a hollow space (SP1) interposed between the substrate (20) of the acoustic wave device (10c) and the mount substrate (2) is formed. In plan view from the first direction (D1), the hollow space (SP1) overlaps the first area (R11).

According to the high frequency module (1a) with the above-described aspect, the distance in the first direction (D1) between the substrate (20) of the acoustic wave device (10c) and the mount substrate (2) can be further reduced. Therefore, the height of the acoustic wave device (10c) can be reduced, and the size of the high frequency module (1a) can be reduced.

In the high frequency module (1) according to an eighth aspect, in the fourth aspect, the mount substrate (2) includes an insulating layer (23) arranged on a principal surface (21) where the acoustic wave device (10 to 10b) is arranged. In an arrangement area (R1) of the principal surface (21) of the mount substrate (2), a thickness of the insulating layer (23) in the first direction (D1) is less than a thickness of the insulating layer (23) other than the arrangement area (R1) of the principal surface (21) of the mount substrate (2) in the first direction (D1), or the insulating layer (23) is not present. The first direction (D1) is a thickness direction of the substrate (20). The arrangement area (R1) of the principal surface (21) of the mount substrate (2) overlaps the acoustic wave device (10 to 10b) in plan view from the first direction (D1).

According to the high frequency module (1) with the above-described structure, the distance in the first direction (D1) between the acoustic wave device (10 to 10b) and the mount substrate (2) can be reduced. Therefore, the height of the high frequency module (1) can be reduced.

In the high frequency module (1) according to a ninth aspect, in any one of the fourth to eighth aspects, the mount substrate (2) has a first electrode (24) connected to the outer connection electrode and a second electrode (25) connected to the outer shield layer (30) of the acoustic wave device (10 to 10b).

According to the high frequency module (1) with the above-described aspect, shieldability of the outer shield layer (30) of the acoustic wave device (10 to 10b) can be improved.

The high frequency module (1; 1a) according to a tenth aspect further includes a first component (4) and a second component (5), in any one of the fourth to ninth aspects. In plan view from a first direction (D1), the acoustic wave device (10) is arranged between the first component (4) and the second component (5). The first direction (D1) is a thickness direction of the substrate (20).

According to the high frequency module (1; 1a) with the above-described aspect, the isolation between the first component (4) and the acoustic wave device (10 to 10c), between the acoustic wave device (10 to 10c) and the second component (5), and between the first component (4) and the second component (5) can be improved.

The high frequency module (1; 1a) according to an eleventh aspect further includes a plurality of acoustic wave devices (10 to 10c), a first component, and a second component, in any one of the fourth to ninth aspects. Each of the plurality of acoustic wave devices (10 to 10c) is the acoustic wave device (10 to 10c) according to any one of the first to third aspects. On a straight line connecting the first component (4) and the second component (5), any one acoustic wave device (10 to 10c) among the plurality of acoustic wave devices (10 to 10c) is arranged. When the second component (5) is viewed from the first component (4), the plurality of acoustic wave devices (10 to 10c) are aligned without a gap.

According to the high frequency module (1; 1a) with the above-described aspect, the isolation between the first component (4) and the acoustic wave device (10 to 10c), between the acoustic wave device (10 to 10c) and the second component (5), and between the first component (4) and the second component (5) can be improved. Furthermore, in the high frequency module (1; 1a), since one acoustic wave device (10 to 10c) is arranged between the first component (4) and the second component (5), the isolation between the first component (4) and the second component (5) is easily improved.

In the high frequency module (1; 1a) according to a twelfth aspect, in the eleventh aspect, the plurality of acoustic wave devices (10) include a first acoustic wave device (10 to 10c) and a second acoustic wave device (10 to 10c). The outer shield layer (30) of the first acoustic wave device (10 to 10c) is in contact with the outer shield layer (30) of the second acoustic wave device (10 to 10c).

According to the high frequency module (1; 1a) with the above-described aspect, the effect of improving the isolation between the first component (4) and the second component (5) by the outer shield layer (30) of the acoustic wave device (10) is further increased.

A communication device (100) according to a thirteenth aspect includes a high frequency module (1; 1a) and a signal processing circuit (17) connected to the high frequency module (1; 1a).

According to the communication device (100) with the above-described aspect, in the high frequency module (1; 1a), the outer shield layer (30) functions as a shielding member between the acoustic wave device (10 to 10c) and another component and between two other components. Furthermore, since the acoustic wave device (10 to 10c) is arranged on the high frequency module (1; 1a) in a state in which the outer connection electrode (40) is directly in contact with the electrode (24) of the mount substrate (2), the height of the acoustic wave device (10 to 10c) can be reduced in the high frequency module (1; 1a).

What is claimed is:

1. An acoustic wave device comprising:
a substrate having a first principal surface and a second principal surface mutually opposed, and side surfaces connecting the first principal surface and the second principal surface together;
an outer connection electrode arranged on the first principal surface of the substrate; and
an outer shield layer arranged on the side surfaces of the substrate, wherein
a tip surface of the outer connection electrode is exposed.

2. The acoustic wave device according to claim 1, further comprising:
a cover layer having a third principal surface and a fourth principal surface mutually opposed, wherein
the third principal surface of the cover layer is opposed to the first principal surface of the substrate,
the fourth principal surface of the cover layer is exposed, and
the tip surface of the outer connection electrode is arranged so as to be flush with the fourth principal surface of the cover layer.

3. The acoustic wave device according to claim 1, further comprising:
a cover layer having a third principal surface and a fourth principal surface mutually opposed, wherein
the third principal surface of the cover layer is opposed to the first principal surface of the substrate,
the fourth principal surface of the cover layer is exposed, and
a distance in a first direction indicating a thickness direction of the substrate between the tip surface of the outer connection electrode and the first principal surface of the substrate is shorter than a distance in the first direction between the fourth principal surface of the cover layer and the first principal surface of the substrate.

4. A high frequency module comprising:
the acoustic wave device according to claim 1; and
a mount substrate where the acoustic wave device is arranged.

5. The high frequency module according to claim 4, wherein
the mount substrate includes an insulating layer arranged on a principal surface where the acoustic wave device is arranged, and
the acoustic wave device is in contact with the insulating layer of the mount substrate in a first direction indicating a thickness direction of the substrate.

6. The high frequency module according to claim 5, wherein
an arrangement area of the principal surface of the mount substrate overlapping the acoustic wave device in plan view from the first direction includes a first area and a second area,
in the first area, a thickness of the insulating layer in the first direction is less than a thickness of the insulating layer in the second area in the first direction or the insulating layer is not present,
in the second area, the acoustic wave device is in contact with the insulating layer of the mount substrate in the first direction, and
the second area surrounds the first area.

7. The high frequency module according to claim 6, wherein
a hollow space interposed between the substrate of the acoustic wave device and the mount substrate is provided, and
in plan view from the first direction, the hollow space overlaps the first area.

8. The high frequency module according to claim 4, wherein
the mount substrate includes an insulating layer arranged on a principal surface where the acoustic wave device is arranged, and
in an arrangement area of the principal surface of the mount substrate overlapping the acoustic wave device in plan view from a first direction indicating a thickness direction of the substrate, a thickness of the insulating layer in the first direction is less than a thickness of the insulating layer other than the arrangement area of the principal surface of the mount substrate in the first direction, or the insulating layer is not present.

9. The high frequency module according to claim 4, wherein
the mount substrate has
a first electrode connected to the outer connection electrode, and
a second electrode connected to the outer shield layer of the acoustic wave device.

10. The high frequency module according to claim 4, further comprising:
a first component; and
a second component, wherein
in plan view from a first direction indicating a thickness direction of the substrate, the acoustic wave device is arranged between the first component and the second component.

11. The high frequency module according to claim 4, further comprising:
a plurality of acoustic wave devices each being the acoustic wave device;
a first component; and
a second component, wherein
any one acoustic wave device among the plurality of acoustic wave devices is arranged on a straight line connecting the first component and the second component, and
when the second component is viewed from the first component, the plurality of acoustic wave devices are aligned without a gap.

12. The high frequency module according to claim 11, wherein
the plurality of acoustic wave devices include a first acoustic wave device and a second acoustic wave device, and
the outer shield layer of the first acoustic wave device is in contact with the outer shield layer of the second acoustic wave device.

13. A communication device comprising:
the high frequency module according to claim 4; and
a signal processing circuit to be connected to the high frequency module.

14. The high frequency module according to claim 5, further comprising:
a first component; and
a second component, wherein
in plan view from a first direction indicating a thickness direction of the substrate, the acoustic wave device is arranged between the first component and the second component.

15. The high frequency module according to claim 6, further comprising:
a first component; and
a second component, wherein
in plan view from a first direction indicating a thickness direction of the substrate, the acoustic wave device is arranged between the first component and the second component.

16. The high frequency module according to claim 7, further comprising:
a first component; and
a second component, wherein
in plan view from a first direction indicating a thickness direction of the substrate, the acoustic wave device is arranged between the first component and the second component.

17. The high frequency module according to claim 8, further comprising:
a first component; and
a second component, wherein
in plan view from a first direction indicating a thickness direction of the substrate, the acoustic wave device is arranged between the first component and the second component.

18. The high frequency module according to claim 9, further comprising:
a first component; and
a second component, wherein
in plan view from a first direction indicating a thickness direction of the substrate, the acoustic wave device is arranged between the first component and the second component.

19. The high frequency module according to claim 5, further comprising:
a plurality of acoustic wave devices each being the acoustic wave device;
a first component; and
a second component, wherein
any one acoustic wave device among the plurality of acoustic wave devices is arranged on a straight line connecting the first component and the second component, and
when the second component is viewed from the first component, the plurality of acoustic wave devices are aligned without a gap.

20. The high frequency module according to claim 6, further comprising:
a plurality of acoustic wave devices each being the acoustic wave device;
a first component; and
a second component, wherein
any one acoustic wave device among the plurality of acoustic wave devices is arranged on a straight line connecting the first component and the second component, and
when the second component is viewed from the first component, the plurality of acoustic wave devices are aligned without a gap.
